(19) United States
(12) Patent Application Publication
(10) Pub. No.: US 2015/0340446 A1
(43) Pub. Date: Nov. 26, 2015

(54) THIN FILM TRANSISTOR SUBSTRATE, METHOD FOR FORMING THE SAME, AND DISPLAY

(71) Applicant: InnoLux Corporation, Miao-Li County (TW)

(72) Inventors: Kuan-Feng LEE, Miao-Li County (TW); Hao-Chuan LAI, Miao-Li County (TW)

(21) Appl. No.: 14/708,491

(22) Filed: May 11, 2015

(30) Foreign Application Priority Data
May 22, 2014 (TW) 103117849

(51) Int. Cl. H01L 29/36; H01L 29/66; H01L 27/12; H01L 29/786

(52) U.S. Cl. CPC H01L 29/36; H01L 29/7869; H01L 29/66969; H01L 27/1225

(57) ABSTRACT

A thin film transistor substrate includes: a substrate; a gate disposed on the substrate; a gate insulating layer disposed on the substrate and covering the gate; an active layer disposed on the gate insulating layer and above the gate, and the active layer has a first oxygen vacancy portion and a second oxygen vacancy portion; a source electrode and a drain electrode disposed on the active layer, the source electrode is connected to the first oxygen vacancy portion, and the drain electrode is connected to the second oxygen vacancy portion.

### CROSS REFERENCE TO RELATED APPLICATIONS

This application claims priority of Taiwan Patent Application No. 103117849, filed on May 22, 2014, the entirety of which is incorporated by reference herein.

### BACKGROUND OF THE INVENTION

1. Field of the Invention

The present invention relates to a thin film transistor substrate, and in particular to a thin film transistor substrate with ohmic contact, a method for forming the same, and a display incorporating the thin film transistor substrate.

2. Description of the Related Art

As display technologics have progressed, human life is getting more convenient through the assistance of display devices. With consumer demand for displays that are light and thin, flat panel displays (FPD) have now become the most popular displays. Among the variety of FPDs, liquid-crystal displays (LCDs) are popular among consumers because of their advantages, such as efficient space utilization, low power consumption, no radiance, and low electromagnetic interference (EMI).

Liquid crystal displays are mainly formed by an active array substrate, a color filter substrate, and a liquid crystal layer located therebetween. The active array substrate includes multiple bottom gate thin film transistors, which serve as driving elements or switch elements of pixels. In the bottom gate thin film transistor, the electrical connection quality between the source electrode and the active layer and between the drain electrode and the active layer affects the electrical performance of the bottom gate thin film transistor (such as the saturated current). Therefore, methods of improving the electrical connection quality between the source electrode and the active layer and between the drain electrode and the active layer are very important.

### BRIEF SUMMARY OF THE INVENTION

An embodiment of the invention provides a thin film transistor substrate which includes: a substrate; a gate disposed on the substrate; a gate insulating layer disposed on the substrate and covering the gate; an active layer disposed on the gate insulating layer and above the gate, and the active layer has a first oxygen vacancy portion and a second oxygen vacancy portion; a source electrode and a drain electrode disposed on the active layer, the source electrode is connected to the first oxygen vacancy portion, and the drain electrode is connected to the second oxygen vacancy portion.

An embodiment of the invention provides a method for forming a thin film transistor substrate, and the method includes: forming a gate on a substrate; forming a gate insulating layer on the substrate to cover the gate; forming an active layer on the gate insulating layer, wherein the active layer is over the gate; forming a first oxygen vacancy portion and a second oxygen vacancy portion in the active layer; and forming a source electrode and a drain electrode on the active layer, wherein the source electrode is connected to the first oxygen vacancy portion, and the drain electrode is connected to the second oxygen vacancy portion.

An embodiment of the invention provides a display, which includes: the thin film transistor substrate mentioned above; a substrate disposed opposite to the thin film transistor substrate; and a display medium disposed between the thin film transistor substrate and the substrate.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A-1E are cross-sectional views showing the steps of forming a thin film transistor substrate in accordance with an embodiment of the present invention;

FIGS. 2A-2E are cross-sectional views showing the steps of forming a thin film transistor substrate in accordance with an embodiment of the present invention;

FIG. 3 shows hysteresis effect measurement results of thin film transistors with different active-layer thicknesses;

FIG. 4 shows the results of a positive gate bias stress test of thin film transistors with different active-layer thicknesses;

FIG. 5 shows the results of a negative gate bias stress test of thin film transistors with different active-layer thicknesses;

FIG. 6 shows the results of a negative gate bias stress test with illumination of thin film transistors with different active-layer thicknesses; and

FIG. 7 is a cross-sectional view of a display of an embodiment of the present invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

It should be understood that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numbers and/or letters in the various examples. This repetition is for the purpose of simplicity and clarity and does not in itself dictate a relationship between the various embodiments and/or configurations discussed. Furthermore, descriptions of a first layer “on,” “overlying,” (and like descriptions) a second layer, include embodiments where the first and second layers are in direct contact and those where one or more layers are interposing the first and second layers.

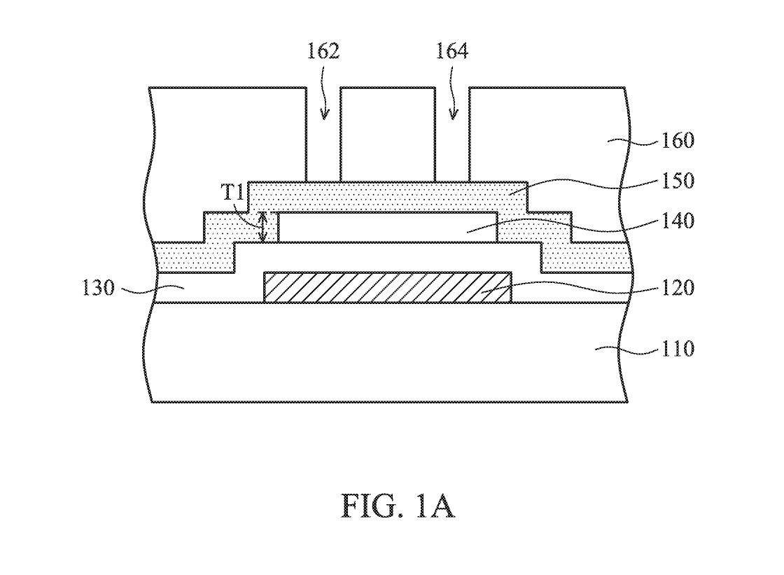

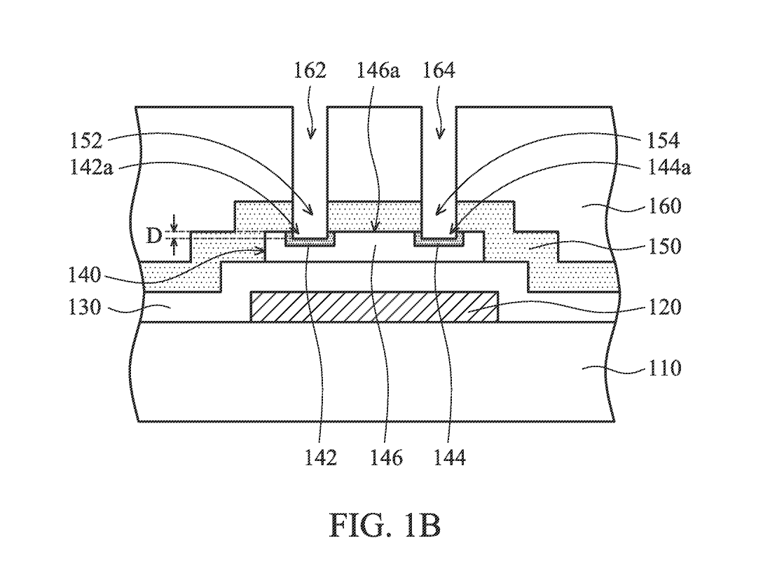

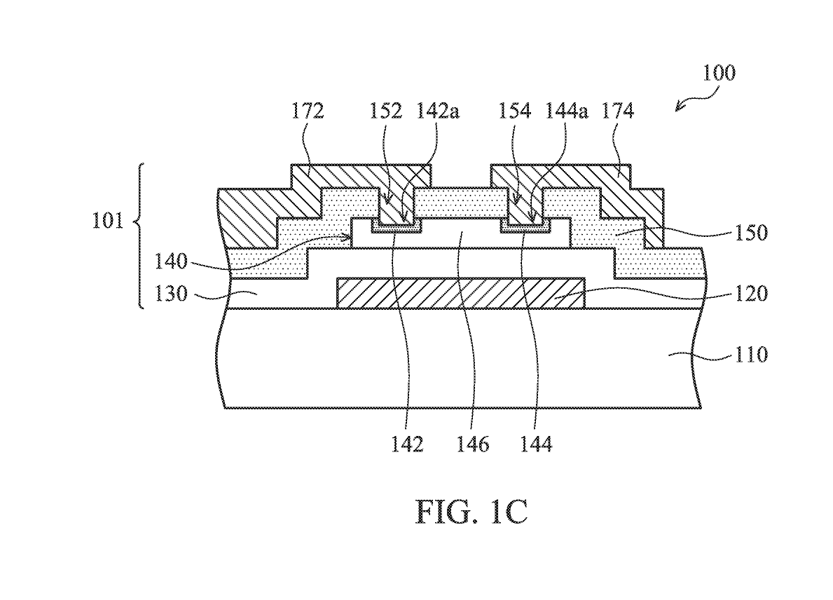

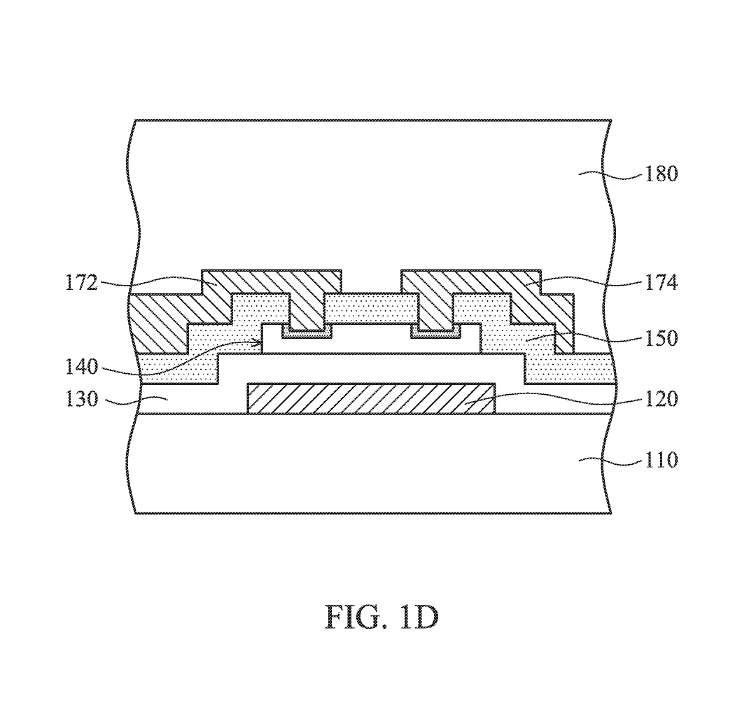

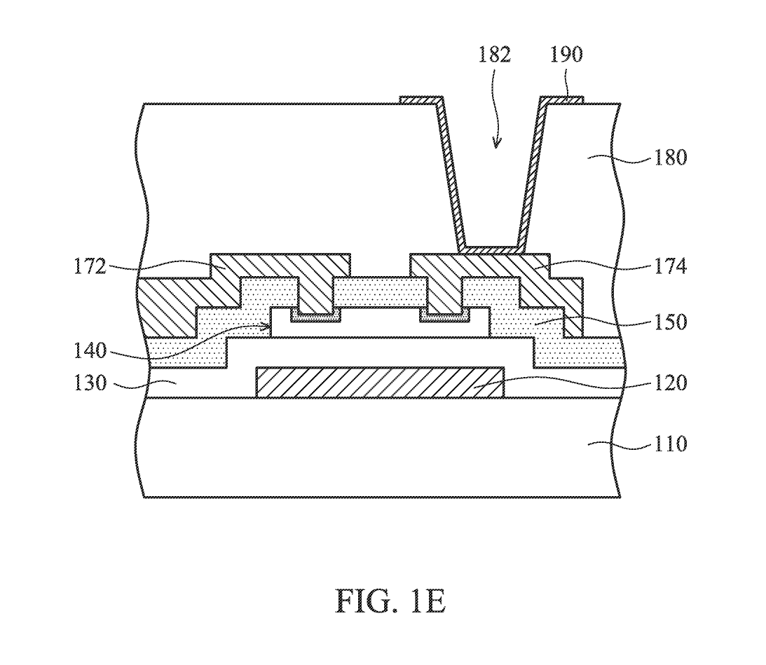

FIGS. 1A-1E are cross-sectional views showing the steps of forming a thin film transistor substrate in accordance with an embodiment of the present invention. Referring to FIG. 1A, a substrate 110 is provided. The substrate 110 is, for example, a glass substrate or a plastic substrate. Thereafter, a gate 120 and a gate insulating layer 130 are formed on the substrate 110. The gate insulating layer 130 covers the gate 120. In one embodiment, the gate 120 includes aluminum (Al), molybdenum (Mo), or another suitable conductive material. The gate insulating layer 130 includes, for example, silicon dioxide, nitrogen dioxide, or another dielectric material with a high dielectric constant.

Then, an active layer 140 is formed on the gate insulating layer 130. The active layer 140 is formed by performing a photolithography process to form a patterned mask and performing an etching process using the patterned mask. The active layer 140 includes, for example, InGaZnO (IGZO), InSnZnO (ITZO), InZnO (IZO), or another metal-oxide-semiconductor material suitable for forming the active layer. In one embodiment, the active layer 140 has a thickness T1 substantially ranging from 200 Å to 900 Å. The thickness T1 of the active layer 140 substantially ranges, for example, from 300 Å to 700 Å.

Thereafter, an etching stop layer 150 is formed on the gate insulating layer 130. The etching stop layer 150 covers the active layer 140. The etching stop layer 150 includes, for example, silicon oxide or another suitable material. Thereafter, in one embodiment, a patterned photoresist layer (also referred to as a patterned mask layer) 160 is formed on the etching stop layer 150. The patterned photoresist layer 160 has two openings 162 and 164 exposing a portion of the etching stop layer 150. The openings 162 and 164 are located above the active layer 140 and corresponding to the active layer 140 in the vertical projection direction.

Thereafter, referring to FIG. 1B, an etching process is performed using the patterned photoresist layer 160 as an etching mask to form a first opening 152 and a second opening 154 in the etching stop layer 150. The first opening 152 and the second opening 154 expose the active layer 140. The first opening 152 is located under the opening 162 and is connected to the opening 162. The second opening 154 is located under the opening 164 and is connected to the opening 164. In one embodiment, the etching process includes a dry etching process. The dry etching process uses an etchant (e.g., an etchant gas), such as tetrafluoromethane (CF4) and oxygen.

The etchant (e.g., an etching gas or an etching liquid) used in the etching process of the present embodiment may react with the active layer 140, which results in an increase of oxygen vacancies in the active layer 140. Therefore, the etching process forms a first oxygen vacancy portion 142 and a second oxygen vacancy portion 144 in the active layer 140 under and exposed by the first opening 152 and the second opening 154. In other words, the first opening 152 and the second opening 154 expose the first oxygen vacancy portion 142 and the second oxygen vacancy portion 144, respectively.

The concentration of the oxygen vacancies in the first oxygen vacancy portion 142 and the second oxygen vacancy portion 144 is greater than that in a first portion 146 of the active layer 140. The first portion 146 is the active layer 140 minus the first oxygen vacancy portion 142 and the second oxygen vacancy portion 144. Therefore, a first carrier concentration (also referred to as a charge concentration) of the first oxygen vacancy portion 142 and the second oxygen vacancy portion 144 is greater than a second carrier concentration of the first portion 146 of the active layer 140.

In one embodiment, the first carrier concentration of the first oxygen vacancy portion 142 and the second oxygen vacancy portion 144 is substantially in a range from 10¹⁹ cm⁻³ to 10²² cm⁻³. In one embodiment, the second carrier concentration of the first portion 146 is substantially in a range from 10¹⁶ cm⁻³ to 10¹⁸ cm⁻³. In the present embodiment, the first oxygen vacancy portion 142 and the second oxygen vacancy portion 144 are both located at a side 146a of the active layer 140.

In one embodiment, during the reaction between the etchant of the etching process and the active layer 140, the etching process also removes a portion of the active layer 140 such that a first recess 142a is formed in the first oxygen vacancy portion 142, and a second recess 144a is formed in the second oxygen vacancy portion 144. The first recess 142a is formed under the first opening 152 and is connected to the first opening 152. The second recess 144a is formed under the second opening 154 and is connected to the second opening 154. The greater the depths of the first recess 142a and the second recess 144a are, the greater the concentration of the oxygen vacancies of the first oxygen vacancy portion 142 and the second oxygen vacancy portion 144 is and/or the greater the sizes of the oxygen vacancy portions 142 and 144 are. In one embodiment, the depths D of the first recess 142a and the second recess 144a each ranges substantially from 50 Å to 400 Å. In one embodiment, the depths D of the first recess 142a and the second recess 144a each ranges substantially from 100 Å to 300 Å.

Then, as shown in FIG. 1C, the patterned photoresist layer 160 is removed. Thereafter, a source electrode 172 and a drain electrode 174 are formed on the etching stop layer 150. The source electrode 172 is filled into the first opening 152 and the first recess 142a and is connected to the first oxygen vacancy portion 142. The drain electrode 174 is filled into the second opening 154 and the second recess 144a and is connected to the second oxygen vacancy portion 144. The source electrode 172 and the drain electrode 174 include aluminum (Al), molybdenum (Mo), and/or another suitable conductive material. In this step, a thin film transistor 101 of the thin film transistor substrate 100 of the present embodiment is substantially formed. In the present embodiment, the thin film transistor 101 at least includes the gate 120, the gate insulating layer 130, the active layer 140, the source electrode 172, and the drain electrode 174.

It should be noted that, in the present embodiment, the first oxygen vacancy portion 142 and the second oxygen vacancy portion 144 with a high carrier concentration are formed under the first openings 152 and the second opening 154, respectively. Therefore, the source electrode 172 filled in the first opening 152 may make good ohmic contact with the first oxygen vacancy portion 142, and the drain electrode 174 filled in the second opening 154 may make good ohmic contact with the second oxygen vacancy portion 144. Therefore, the first oxygen vacancy portion 142 and the second oxygen vacancy portion 144 may effectively reduce the contact resistance between the source electrode 172 and the active layer 140 and between the drain electrode 174 and the active layer 140, which effectively improve the saturation current (Ion) of the thin film transistor 101 of the present embodiment.

Afterwards, referring to FIG. 1D, an insulating layer 180 may be optionally formed on the etching stop layer 150. The insulating layer 180 covers the source electrode 172 and the drain electrode 174. The insulating layer 180 may be a single-layer structure or a multi-layer structure. The insulating layer 180 includes silicon oxide, silicon nitride, polytetrafluoroethylene (PFA), or another suitable insulating material.

Thereafter, as shown in FIG. 1E, a through hole 182 is formed in the insulating layer 180 to expose a portion of the drain electrode 174 by, for example, a photolithography process and an etching process. Thereafter, a conductive layer 190 is formed on the insulating layer 180. The conductive layer 190 extends into the through hole 182 and is connected to the drain electrode 174. The conductive layer 190 includes a transparent conductive material (e.g., indium tin oxide) or metal (e.g., copper). In another embodiment (not shown), the through hole 182 exposes the source electrode 172, and the conductive layer 190 extends into the through hole 182 to connect the source electrode 172.

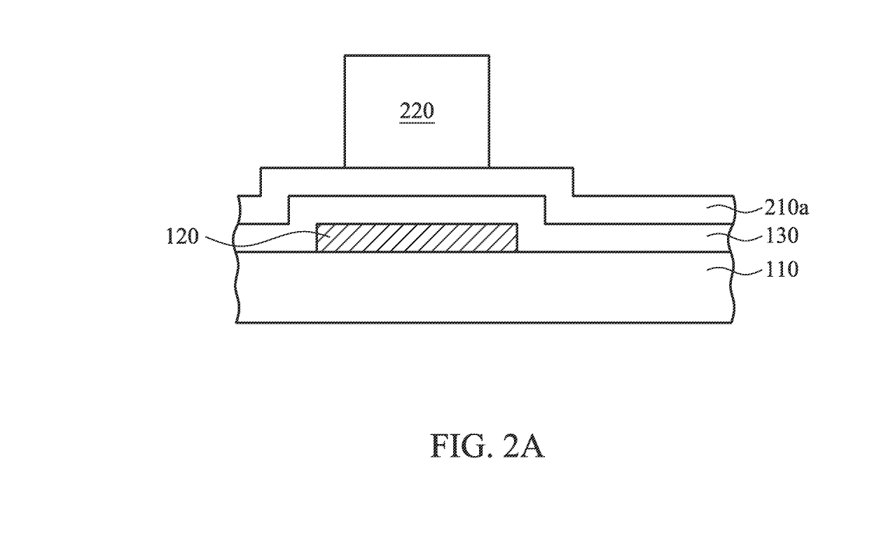

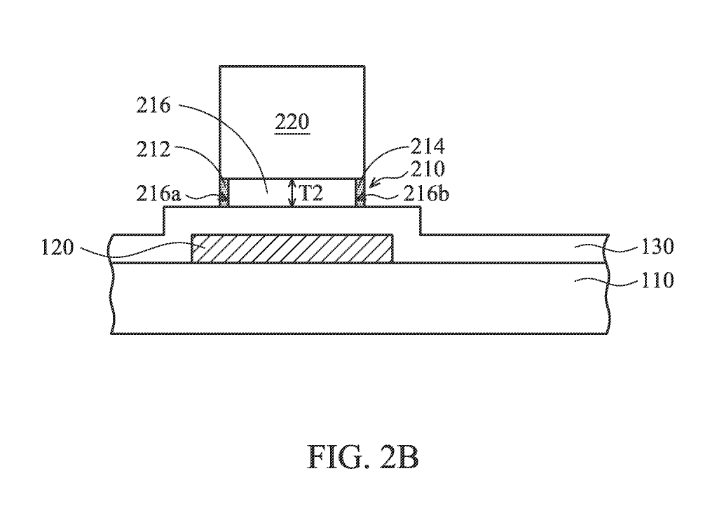

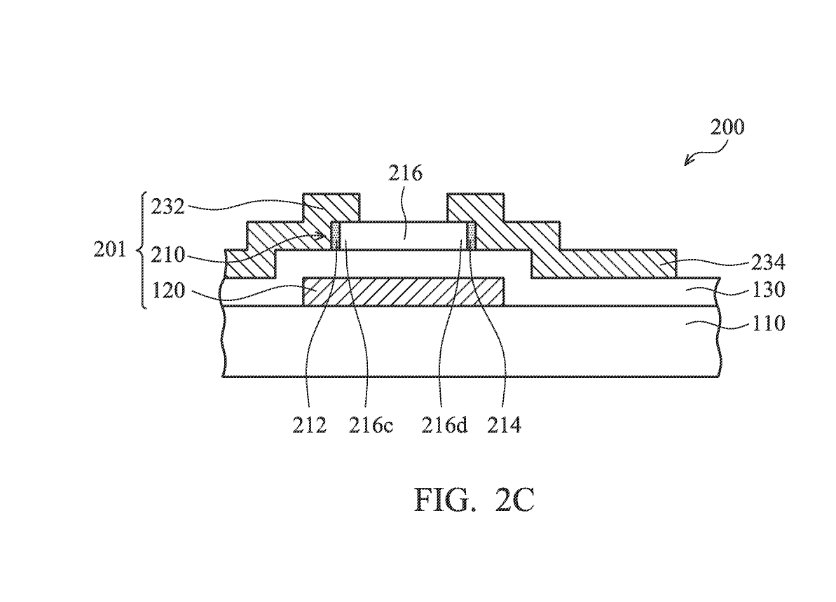

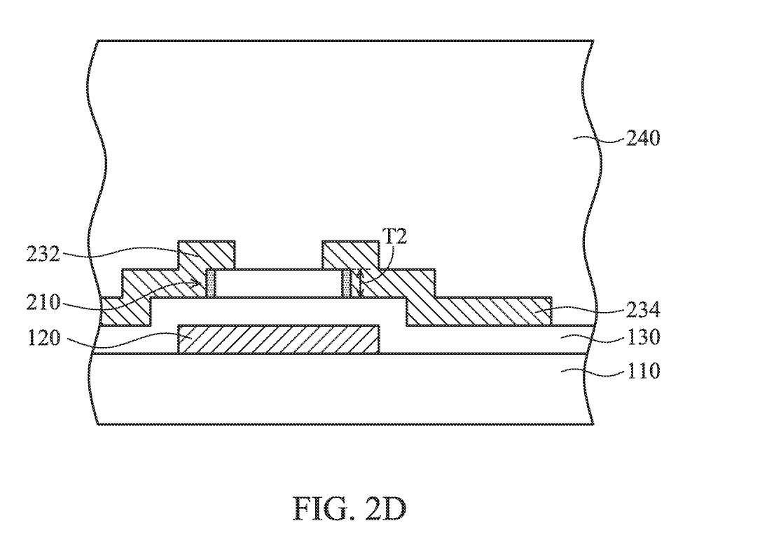

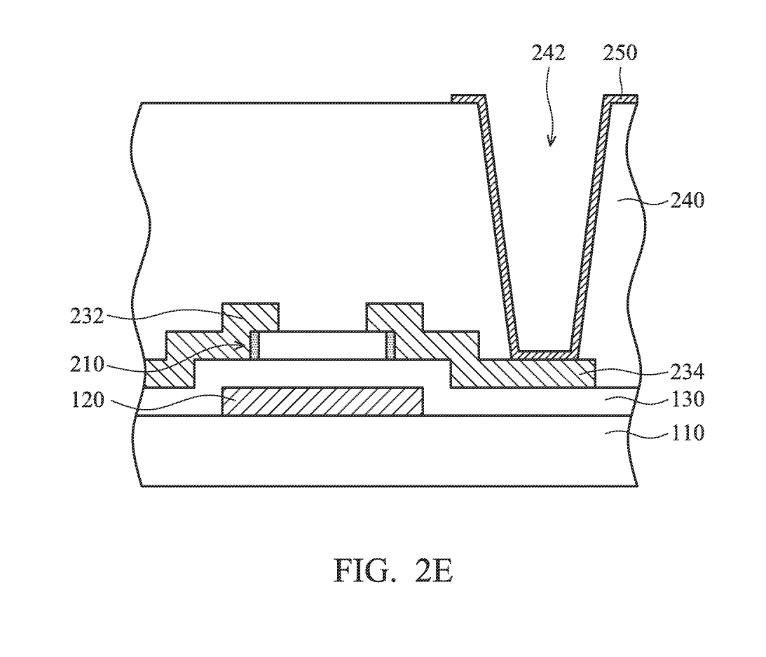

FIGS. 2A-2E are cross-sectional views showing the steps of forming a thin film transistor substrate in accordance with an embodiment of the present invention. Referring to FIG. 2A, a substrate 110 is provided. The substrate 110 is, for example, a glass substrate or a plastic substrate. Thereafter, a gate 120 and a gate insulating layer 130 are formed on the substrate 110. The gate insulating layer 130 covers the gate 120. In one embodiment, the gate 120 includes aluminum (Al), molybdenum (Mo), or another suitable conductive material. The gate insulating layer 130 includes, for example, silicon dioxide or another dielectric material with a high dielectric constant.

Then, an active material layer 210a is formed on the gate insulating layer 130. The active material layer 210a includes, for example, InGaZnO (IGZO), InSnZnO (ITZO), InZnO (IZO), or another metal-oxide-semiconductor material suitable for forming an active layer. Afterwards, a patterned photoresist layer (also referred to as a patterned mask layer) 220 is formed on the active material layer 210a. The patterned photoresist layer 220 corresponds to the gate 120 and is disposed over the gate 120.

Then, referring to FIG. 2B, an etching process is performed using the patterned photoresist layer 220 as an etching mask to remove the active material layer 210a exposed by the patterned photoresist layer 220 so as to form an active layer 210. In one embodiment, the active layer 210 has a thickness T2 substantially ranging from 200 Å to 900 Å. The thickness T2 of the active layer 210 substantially ranges, for example, from 300 Å to 700 Å.

In one embodiment, the etching process includes a wet etching process. An etchant (or an etching liquid) used in the wet etching process includes, for example, oxalic acid. In another embodiment, the etching process includes a dry etching process. The etchant (i.e., an etching gas) used in the dry etching process includes, for example, boron trichloride (BCl3) and oxygen, sulfur hexafluoride (SF6) and oxygen, or tetrafluoromethane (CF4) and oxygen. In another embodiment, the etching process includes performing a wet etching process (using, for example, oxalic acid as an etchant); and then performing a dry etching process (using, for example, tetrafluoromethane and oxygen as an etchant).

The etchant (e.g., an etching gas or an etching liquid) used in the etching process of the present embodiment may react with the active layer 210, which results in an increase of oxygen vacancies in the active layer 210. Therefore, the etching process forms a first oxygen vacancy portion 212 and a second oxygen vacancy portion 214 at two ends of the active layer 210 exposed by the patterned photoresist layer 220, respectively.

A concentration of the oxygen vacancies of the first oxygen vacancy portion 212 and the second oxygen vacancy portion 214 is greater than that of a first portion 216 of the active layer 210. The first portion 216 is the active layer 210 minus the first oxygen vacancy portion 212 and the second oxygen vacancy portion 214. Therefore, a first carrier concentration (also referred to as a charge concentration) of the first oxygen vacancy portion 212 and the second oxygen vacancy portion 214 is greater than a second carrier concentration of the first portion 216 of the active layer 210.

In one embodiment, the first carrier concentration of the first oxygen vacancy portion 212 and the second oxygen vacancy portion 214 is greater than about 10¹⁹ cm⁻³. In one embodiment, the second carrier concentration of the first portion 216 is substantially in a range from 10¹⁶ cm⁻³ to 10¹⁸ cm⁻³. In the present embodiment, the first oxygen vacancy portion 212 and the second oxygen vacancy portion 214 are located at two opposite sides 216a and 216b of the active layer 210, respectively.

Then, as shown in FIG. 2C, the patterned photoresist layer 220 is removed. Then, a source electrode 232 and a drain electrode 234 are formed on the first oxygen vacancy portion 212 and the second oxygen vacancy portion 214 of the active layer 210, respectively. The source electrode 232 is connected to the first oxygen vacancy portion 212 and a first end 216c of the active layer 210 and extends onto the gate insulating layer 130. The drain electrode 234 is connected to the second oxygen vacancy portion 214 and a second end 216d of the active layer 210 and extends onto the gate insulating layer 130. The source electrode 232 and the drain electrode 234 include aluminum (Al), molybdenum (Mo), and/or another suitable conductive material. In this step, a thin film transistor 201 of the thin film transistor substrate 200 of the present embodiment is substantially formed. In the present embodiment, the thin film transistor 201 at least includes the gate 120, the gate insulating layer 130, the active layer 210, the source electrode 232, and the drain electrode 234.

It should be noted that, in the present embodiment, the source electrode 232 may make good ohmic contact with the first oxygen vacancy portion 212, and the drain electrode 234 may make good ohmic contact with the second oxygen vacancy portion 214. Therefore, the first oxygen vacancy portion 212 and the second oxygen vacancy portion 214 may effectively reduce the contact resistance between the source electrode 232 and the active layer 210 and between the drain electrode 234 and the active layer 210, which effectively improves the saturation current (Ion) of the thin film transistor 201 of the present embodiment.

Afterwards, referring to FIG. 2D, an insulating layer 240 may be optionally formed on the gate insulating layer 130. The insulating layer 240 covers the source electrode 232, the drain electrode 234, and the active layer 210. The insulating layer 240 may be a single-layer structure or a multi-layer structure. The insulating layer 240 includes silicon oxide, silicon nitride, polytetrafluoroethylene (PFA), or another suitable insulating material.

Thereafter, referring to FIG. 2E, a through hole 242 is formed in the insulating layer 240 to expose a portion of the drain electrode 234 by, for example, a photolithography process and an etching process. Thereafter, a conductive layer 250 is formed on the insulating layer 240. The conductive layer 250 extends into the through hole 242 and is connected to the drain electrode 234. The conductive layer 250 includes a transparent conductive material (e.g., indium tin oxide) or metal (e.g., copper). In another embodiment (not shown), the through hole 242 exposes the source electrode 232, and the conductive layer 250 extends into the through hole 242 to connect the source electrode 232.

In the embodiments of FIGS. 1A-1E and FIGS. 2A-2E, the thickness T1 of the active layer 140 and the thickness T2 of the active layer 210 each ranges substantially from 200 Å to 900 Å. The thickness T2 of the active layer 210 substantially ranges, for example, from 300 Å to 700 Å. The thickness T1 of the active layer 140 and the thickness T2 of the active layer 210 may be maintained in a proper range. No matter whether the active layer 140 or 210 is too thin or too thick, the electrical properties of the thin film transistor are affected adversely. The electrical property test results of the thin film transistors with the active layers with different thicknesses are provided as follows.

FIG. 3 shows hysteresis effect measurement results of thin film transistors with different active-layer thicknesses. FIG. 3 shows the relationships between the active-layer thicknesses of the thin film transistors and the threshold voltages. The closer to zero the threshold voltage of the thin film transistor is, the smaller the hysteresis effect is, which leads to a better electrical performance. FIG. 3 shows that the threshold voltages of the thin film transistors having the active layer thickness ranging from 500 Å to 1000 Å are closer to zero than those of other thin film transistors. Therefore, they have better electrical performance.

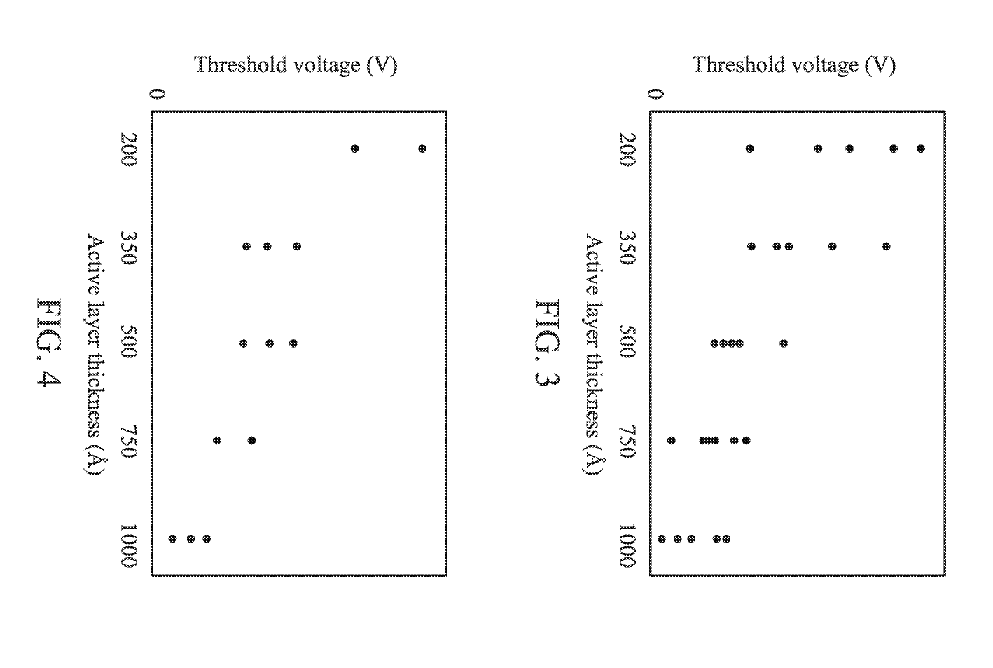

FIG. 4 shows results of a positive gate bias stress test of thin film transistors with different active-layer thicknesses. In the test, a positive bias voltage is applied to each of the gates of the thin film transistors. Afterwards, the threshold voltages of the thin film transistors are measured. FIG. 4 shows that the threshold voltages of the thin film transistors having the active layer thickness ranging from 500 Å to 1000 Å is closer to zero than those of other thin film transistors. Therefore, they have better electrical performance.

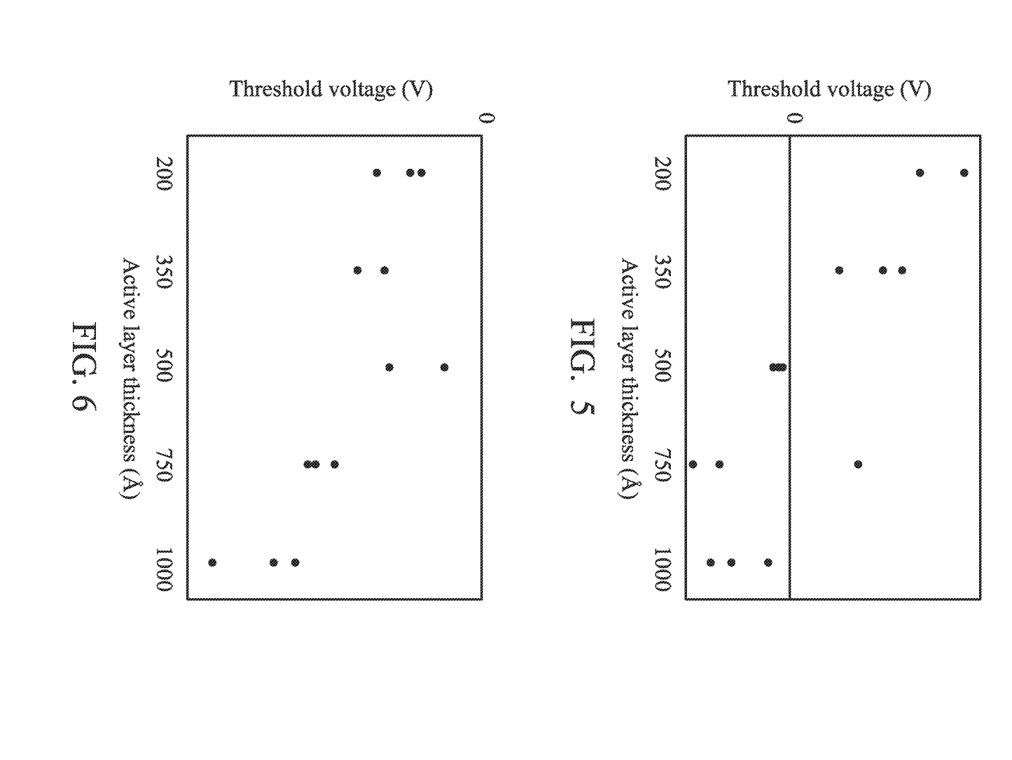

FIG. 5 shows the results of a negative gate bias stress test of thin film transistors with different active-layer thicknesses. In the tests, a negative bias voltage (−30V) is applied to each of the gates of the thin film transistors for more than one hour. Afterwards, the threshold voltages of the thin film transistors are measured. FIG. 5 shows that the threshold voltages of the thin film transistors having the active layer thickness ranging from 350 Å to 750 Å is closer to zero than those of other thin film transistors. Therefore, they have better electrical performance.

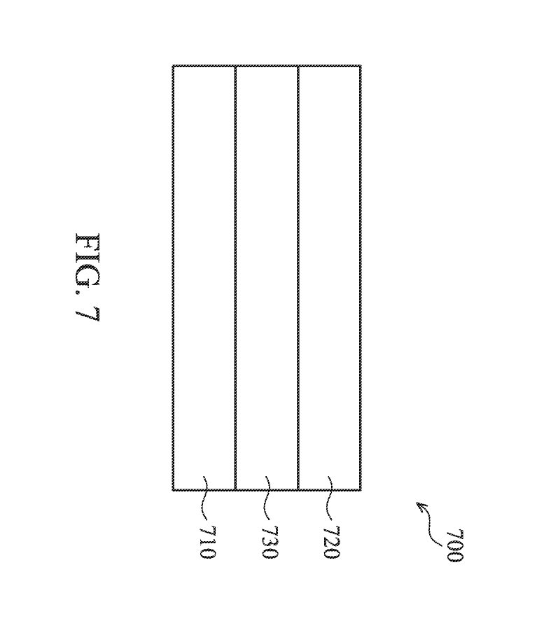

FIG. 6 shows the results of a negative gate bias stress test with illumination of thin film transistors with different active-layer thicknesses. In the test, an illumination and a negative bias voltage (−30V) is applied to each of the gates of the thin film transistors for more than one hour. Afterwards, the threshold voltages of the thin film transistors are measured. FIG. 6 shows that the threshold voltages of the thin film transistors having the active layer thickness ranging from 200 Å to 500 Å is closer to zero than those of other thin film transistors. Therefore, they have better electrical performance.

As illustrated in FIGS. 3-6, when the active layer thickness is greater (more than 500 Å), the hysteresis effect of the thin film transistor is smaller, and the results of the positive gate bias stress test and the negative gate bias stress test are good. However, the results of the negative gate bias stress test with illumination are bad. When the active layer thickness is smaller (smaller than 500 Å), the results of the tests are opposite to the results when the active layer thickness is greater (more than 500 Å). Therefore, in order to prevent some properties of the thin film transistors from degrading, it is designed to form an active layer with a middle thickness for balance. As a result, the active layer thickness of the thin film transistor may be set to a range of 200 Å to 900 Å. In another embodiment, the active layer thickness of the thin film transistor is set to a range of 300 Å to 700 Å.

FIG. 7 is a cross-sectional view of a display of an embodiment of the present invention. Referring to FIG. 7, a display 700 of the present embodiment includes a thin film transistor substrate 710, a substrate 720, and a display medium 730 sandwiched between the thin film transistor substrate 710 and the substrate 720. The thin film transistor substrate 710 includes the thin film transistors 101 and/or the thin film transistors 201 mentioned above. The display medium 730 may be a liquid crystal layer or an organic light emitting layer. The substrate 720 is, for example, a color filter substrate or a transparent substrate.

As described above, in the present invention, since the active layer of the thin film transistor has the oxygen vacancy portions, the source electrode and the drain electrode may make good ohmic contact with the oxygen vacancy portions. Therefore, the saturation current of the thin film transistor of the present invention is effectively improved.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A thin film transistor substrate, comprising:
a substrate;
a gate disposed on the substrate;
a gate insulating layer disposed on the substrate and covering the gate;
an active layer disposed on the gate insulating layer and above the gate, and the active layer has a first oxygen vacancy portion and a second oxygen vacancy portion; and
a source electrode and a drain electrode disposed on the active layer, the source electrode is connected to the first oxygen vacancy portion, and the drain electrode is connected to the second oxygen vacancy portion.

2. The thin film transistor substrate as claimed in claim 1, wherein a first carrier concentration of the first oxygen vacancy portion and the second oxygen vacancy portion is greater than a second carrier concentration of a first portion of the active layer, and the first portion is the active layer minus the first oxygen vacancy portion and the second oxygen vacancy portion.

3. The thin film transistor substrate as claimed in claim 2, wherein the first carrier concentration of the first oxygen vacancy portion and the second oxygen vacancy portion is substantially in a range from 10¹⁹ cm⁻³ to 10²² cm⁻³.

4. The thin film transistor substrate as claimed in claim 2, wherein the second carrier concentration of the first portion is substantially in a range from 10¹⁶ cm⁻³ to 10¹⁸ cm⁻³.

5. The thin film transistor substrate as claimed in claim 1, wherein the first oxygen oxygen vacancy portion has a second recess, and the drain electrode fills the second recess.

6. The thin film transistor substrate as claimed in claim 5, wherein depths of the first recess and the second recess each ranges substantially from 100 Å to 300 Å.

7. The thin film transistor substrate as claimed in claim 1, wherein the first oxygen vacancy portion and the second oxygen vacancy portion are both located at a side of the active layer.

8. The thin film transistor substrate as claimed in claim 1, further comprising:
an etching stop layer disposed on the gate insulating layer and covering the active layer, wherein the etching stop layer has a first opening and a second opening, the first opening exposes the first oxygen vacancy portion, the second opening exposes the second oxygen vacancy portion, the source electrode is disposed in the first opening, and the drain electrode is disposed in the second opening.

9. The thin film transistor substrate as claimed in claim 1, wherein the first oxygen vacancy portion and the second oxygen vacancy portion are located at two opposite sides of the active layer, respectively.

10. The thin film transistor substrate as claimed in claim 1, wherein the source electrode is connected to the first oxygen vacancy portion and a first end of the active layer, and the drain electrode is connected to the second oxygen vacancy portion and a second end of the active layer.

11. The thin film transistor substrate as claimed in claim 1, wherein a thickness of the active layer ranges substantially from 300 Å to 700 Å.

12. A method for forming a thin film transistor substrate, comprising:
forming a gate on a substrate;
forming a gate insulating layer on the substrate to cover the gate;
forming an active layer on the gate insulating layer, wherein the active layer is over the gate;
forming a first oxygen vacancy portion and a second oxygen vacancy portion in the active layer; and
forming a source electrode and a drain electrode on the active layer, wherein the source electrode is connected to the first oxygen vacancy portion, and the drain electrode is connected to the second oxygen vacancy portion.

13. The method for forming a thin film transistor substrate as claimed in claim 12, wherein the step of forming the first oxygen vacancy portion and the second oxygen vacancy portion and the step of forming the source electrode and the drain electrode comprise:
before forming the source electrode and the drain electrode, forming an etching stop layer on the gate insulating layer to cover the active layer;
performing an etching process to form a first opening and a second opening in the etching stop layer, wherein the first opening and the second opening expose the active layer, and the first oxygen vacancy portion and the second oxygen vacancy portion are formed in the active layer exposed by the first opening and the second opening; and
forming the source electrode and the drain electrode on the etching stop layer, wherein the source electrode is filled into the first opening and is connected to the first oxygen vacancy portion, and the drain electrode is filled into the second opening and is connected to the second oxygen vacancy portion.

14. The method for forming a thin film transistor substrate as claimed in claim 13, wherein the etching process comprises a dry etching process.

15. The method for forming a thin film transistor substrate as claimed in claim 12, wherein the step of forming the active layer, the step of forming the first oxygen vacancy portion and the second oxygen vacancy portion, and the step of forming the source electrode and the drain electrode comprise:
forming an active material layer on the gate insulating layer;
patterning the active material layer to form the active layer and to form the first oxygen vacancy portion and the second oxygen vacancy portion at two ends of the active layer, respectively; and
forming the source electrode and the drain electrode to cover the first oxygen vacancy portion and the second oxygen vacancy portion, respectively.

16. The method for forming a thin film transistor substrate as claimed in claim 15, wherein the etching process comprises a wet etching process.

17. The method for forming a thin film transistor substrate as claimed in claim 15, wherein the etching process comprises a wet etching process and a dry etching process.

18. The method for forming a thin film transistor substrate as claimed in claim 13, wherein in the step of performing the etching process to form the first opening and the second opening in the etching stop layer, the etching process comprises removing a portion of the active layer to form a first recess in the first oxygen vacancy portion and a second recess in the second oxygen vacancy portion.

19. A display, comprising:
a thin film transistor substrate as claimed in claim 1;
a substrate disposed opposite to the thin film transistor substrate; and
a display medium disposed between the thin film transistor substrate and the substrate.

20. The display as claimed in claim 19, wherein the display medium comprises a liquid crystal layer or an organic light emitting layer.
